(19) United States
(12) Patent Application Publication
(10) Pub. No.: US 2004/0099862 A1
(43) Pub. Date: May 27, 2004

(54) Organic EL device and repair method thereof

(76) Inventors: Harumi Suzuki, Kariya-city (JP); Kahoru Mori, Toyokawa-city (JP); Hiromichi Kato, Kariya-city (JP); Shoichi Kawai, Kuwana-city (JP)

Correspondence Address: POSZ & BETHARDS, PLC, 11250 ROGER BACON DRIVE, SUITE 10, RESTON, VA, 20190, US

(21) Appl. No.: 10/718,619

(22) Filed: Nov. 24, 2003

(30) Foreign Application Priority Data
Nov. 27, 2002 (JP) 2002-343982
Jan. 7, 2003 (JP) 2003-1218

(51) Int. Cl. H01L 35/24

(52) U.S. Cl. 257/40

(57) ABSTRACT

An organic EL device includes pixels disposed with an organic layer including a light-emitting layer 33 between lower electrodes and upper electrodes. A backward bias voltage equal to or less than the withstand voltage of the organic layer in a voltage application condition at the time of use is applied, and preferably a backward bias voltage that is ½ of, or less than ½ of, the withstand voltage of the organic layer is applied. Thus, using the withstand voltage of the organic layer in the voltage application condition at the time of use as a guide, the value of the backward bias voltage for self-repair can be set to an appropriate magnitude and defective portions of the pixels can be self-repaired.

### CROSS REFERENCE TO RELATED APPLICATIONS

This application is based upon, claims the benefit of priority of, and incorporates by reference the contents of, Japanese Patent Application No. 2002-343982 filed on Nov. 27, 2002 and Japanese Patent Application No. 2003-1218 filed on Jan. 7, 2003.

### FIELD OF THE INVENTION

The present invention relates to an organic electroluminescence (EL) panel and a repair method thereof, and in particular to an organic EL panel that has excellent light-emitting stability where poor display such as lines and pixel defects resulting from the short-circuiting of lower and upper electrodes at the time of use is suppressed.

### BACKGROUND OF THE INVENTION

An organic EL panel includes pixels disposed with an organic layer including a light-emitting layer comprising an organic EL material between pairs of electrodes, i.e., lower electrodes and upper electrodes. The driving of the organic EL device is conducted by applying pulse voltages to the pixels so that a forward bias voltage is applied at the time light is to be emitted and a backward bias voltage is applied at the time light is not to be emitted.

Organic EL devices have excellent visibility because they are self-luminous, and weight reduction including a drive circuit is possible because the panels can be driven with a low voltage of several volts to several tens of volts. Thus, their application as thin-film displays, illumination devices and backlights can be expected.

However, in organic EL display devices, defective portions where withstand voltage between the lower and upper electrodes locally drops easily arise due to a deterioration in organic material or inter-dispersion of the material resulting from an electric field or heat, or the intervention of foreign matter. As a result, sometimes short-circuiting of the lower and upper electrodes occurs at the defective portions.

As countermeasures for these drawbacks, conventionally, a method where the upper electrodes, which are electron implantation electrodes, are anodized and self-repaired by applying a backward pulse voltage (backward bias voltage) thereto (see JP-A-11-40346) and a method where the upper electrodes are scattered and self-repaired (see JP-A-11-162637, pp. 3-6, FIGS. 2 and 3) have been known. The basic concept of this technique is that only the upper electrodes are scattered by the voltage energy of the backward bias pulse.

Also, among conventional organic EL display devices, a device has been proposed where a protective film formed by successively laminating an inorganic film and a resin film is disposed on upper electrodes so as to cover pixels formed by successively laminating a lower electrode, an organic layer including a light-emitting layer, and an upper electrode (e.g., see JP-A-2000-223264). According to this, the organic layer is protected by the protective film from external water and oxygen.

However, the above conventional method do not apply the aforementioned conventional self-repair methods to organic EL display devices including a protective film such as the one described in JP-A-2000-223264. Further, according to the investigations of the present inventors, sometimes short-circuiting of the lower and upper electrodes in the above-described defective portions occurs even in organic EL display devices including a protective film.

Here, even if a conventional self-repair method is simply applied, the upper electrodes are not oxidized because the pixels cannot enter in a case where an inorganic protective film and a resin protective film are disposed on the upper portions of the pixels. Also, because the inorganic protective film and the resin protective film are disposed on the upper portions, it is also impossible to scatter the upper electrodes. For this reason, it has been difficult to reliably self-repair short-circuited portions of the lower and upper electrodes.

In the aforementioned conventional countermeasure for preventing short-circuiting of the lower and upper electrodes, the parameters determining the voltage applied for the self-repair are determined by conditions such as the magnitude of the backward bias voltage and the pulse width thereof and by the thickness of Al comprising the upper electrodes.

However, when the present inventors investigated this conventional technique, they discovered that it was impossible to sufficiently realize self-repair only with these parameters.

Specifically, when a backward bias voltage of 35 V was applied in the Examples of JP-A-11-162637, there were cases where the voltage energy of the backward bias pulse was too large and all of the upper electrodes ended up scattering only at defective portions of the pixels. Conversely, with a backward bias voltage of 15 V, there were cases where scattering of the upper electrodes became insufficient at the defective portions, self-repair did not effectively occur, and short-circuiting of the lower and upper electrodes ended up occurring.

In this manner, although methods for applying a backward bias voltage to the pixels have conventionally been proposed with the objective of preventing short-circuiting of the lower and upper electrodes, it has been difficult to determine application conditions of the backward bias voltage such that self-repair can be reliably achieved.

### SUMMARY OF THE INVENTION

Thus, in light of the above-described problems, it is a first object of the present invention to provide an organic EL device and a repair method thereof that can reliably achieve self-repair of pixels.

It is a second object of the present invention to ensure that, in an organic EL display device where a protective film is disposed on upper electrodes so as to cover pixels, short-circuited portions of lower and upper electrodes can be appropriately self-repaired.

In order to achieve the first object, the present inventors understood as a result of their extensive research that a self-repair action can be effectively realized by devoting attention to the withstand voltage (or dielectric strength) of an organic layer and adopting an application method of a backward bias voltage and an element structure corresponding to that withstand voltage. In other words, it was understood that, not only the scattering of the upper electrodes, but the organic layer also participates as a mechanism of scattering the upper electrodes.

The withstand voltage of the organic layer is defined as follows. Specifically, it is the withstand voltage of the organic layer in the voltage application condition at the time of use. The withstand voltage of the organic layer is, from the principle of the organic EL device, the withstand voltage at the time the backward bias voltage is applied. Additionally, the withstand voltage of the organic layer is dependent on the method of applying the backward bias voltage.

Thus, in evaluating the withstand voltage, the backward bias voltage should be set on the basis of a voltage measured in a state that is the same as a pulse width defined by duty ratio and frequency when the panel is actually driven.

From this, the evaluation of the withstand voltage of the organic layer was conducted in the voltage application condition at the time of use where a pulse voltage having a predetermined duty ratio and a predetermined pulse width was applied to the pixels and a current was directed in the forward direction, whereby light was emitted, and a backward bias voltage was applied at the time light was not to be emitted (see FIG. 3).

During this operation, the current in the forward direction was held constant (i.e., light-emitting luminance was substantially constant), and the backward bias voltage where light was not emitted served as the withstand voltage while the backward bias voltage was increased. A method where the backward bias voltage was raised in increments of several volts while the retention time per voltage was set to be 5 seconds or more and 1 minute or less was used as a way of changing the backward bias voltage (see FIG. 4).

When the backward bias voltage is raised in this manner, part or all of the upper electrodes in the pixels is scattered. The value of the backward bias voltage at this time is defined as the withstand voltage of the organic layer. According to this method, a substantially constant value is obtained as the withstand voltage of the organic layer in the voltage application condition at the time of use.

The present invention was created by determining the withstand voltage of an organic layer in an organic EL device and using this withstand voltage.

Namely, a first aspect of the invention is an organic EL device including pixels disposed with an organic layer including a light-emitting layer between lower electrodes and upper electrodes, wherein the pixels can repair themselves when a backward bias voltage equal to or less than the withstand voltage of the organic layer in a voltage application condition at the time of use is applied thereto.

According to this, the value of the backward bias voltage for self-repair can be determined to an appropriate magnitude using the withstand voltage of the organic layer in the voltage application condition at the time of use as a guide. In other words, with respect to the voltage condition applied during use, the backward bias voltage applied at the time light is not to be emitted is set to a magnitude that is equal to or less than the withstand voltage of the organic layer, whereby setting of an excessive backward bias voltage where all of the upper electrodes end up scattering can be prevented.

Also, because the withstand voltage of the organic layer is used as a guide, the magnitude of the backward bias voltage is allowed as far as a magnitude that is equal to or less than the withstand voltage. Thus, a case where the backward bias voltage is too small and self-repair becomes insufficient can be prevented.

In this manner, according to the invention, an organic EL device and an organic EL device repair method where self-repair of pixels at the time of use can be realized more reliably than has conventionally been the case can be provided.

Here, the self-repair referred to is when part of the upper electrode-specifically, the portion of the upper electrode positioned above a defective portion-scatters, the space between the lower and upper electrodes becomes electrically open at this scattered portion, and the defect does not advance any further into the surrounding area.

More fully, although a partial defect remains as the pixel, the withstand voltage of the pixel is recovered and the pixel is able to emit light. Moreover, the self-repair is something where a phenomenon in which short-circuiting with the lower electrode is prevented by the remaining upper electrode after scattering being oxidized and insulated is included.

In a second aspect of the invention, the withstand voltage of the organic layer is the withstand voltage when the organic EL device is driven for 1 minute or less in the voltage application condition at the time of use.

Although the withstand voltage of the organic layer drops in accompaniment with the lapse of use time, it is best to use the withstand voltage at the early stage of use in order for the invention to exhibit effects over the entire time of use. This initial withstand voltage can be the withstand voltage when the organic EL device is driven for 1 minute or less in the voltage application condition at the time of use.

In a third aspect of the invention, the backward bias voltage is ½ of, or less than ½ of, the withstand voltage of the organic layer.

Even if the backward bias voltage is equal to or less than the withstand voltage of the organic layer, there are cases where, depending on the element structure, the upper electrodes of the overall pixels are scattered. Thus, by setting the backward bias voltage to be ½ of, or less than ½ of, the withstand voltage of the organic layer, it is possible to reliably achieve scattering of the upper electrodes of only sites that one wishes to have self-repaired, regardless of the element structure.

In a fourth aspect of the invention, when the withstand voltage of the organic layer is expressed as an electric field intensity per unit thickness of the organic layer, the electric field intensity is 3×10⁶ V/cm or greater.

It was understood that, in the organic EL device, the withstand voltage of the organic layer can be defined by the total thickness thereof regardless of the type of organic material. Additionally, a panel where the electric field intensity is 3×10⁶ V/cm or greater can be used as the organic EL device. According to this, the effects of the present embodiment can be effectively exhibited.

In a fifth aspect of the invention, when the withstand voltage of the organic layer is expressed as an electric field intensity per unit thickness of the organic layer, the electric field intensity is 3.4×10⁶ V/cm or greater excluding a conductive organic film from the organic layer in a case where the electric field intensity is calculated.

In the organic EL device, in a case where the thickness of the organic film using a porphyrin conductive material typified by copper phthalocyanine differs by a compared panel, particularly as the thickness thereof becomes thicker to about equal to or greater than 30 nm, sometimes the electric field intensity is not constant.

It was understood that, in order to more precisely compare the electric field intensity, it is preferable for the conductive organic film to be removed from the organic layer. In this case, when the electric field intensity of the fourth aspect is reassessed, the electric field intensity becomes 3.4×10⁶ V/cm or greater.

According to this, the effect of the above-described means can be effectively exhibited. The important concept here is that the porphyrin conductive material typified by copper phthalocyanine contributes as a resist or and not a semiconductor (insulator) having withstand voltage.

In a sixth aspect of the invention, when the backward bias voltage is represented as Vr, the thickness of the upper electrodes is represented as Da, and the ratio Vr/Da between Vr and Da is represented as Xa, Xa is 2.2×10⁶ V/cm or greater.

When the backward bias voltage is too small and the upper electrodes are too thick, it becomes difficult for the upper electrodes to scatter and self-repair. With respect to this point, by setting the ratio Vr/Da=Xa between the backward bias voltage Vr and the upper electrode thickness Da to 2.2×10⁶ V/cm or greater, self-repair can be conducted more appropriately (see FIG. 7), which is preferable.

In a seventh aspect of the invention, Xa is 2.2×10⁶ V/cm or greater as a result of the thickness Da of the upper electrodes being thinned to 100 nm or less.

As a method for realizing the value of Xa in the sixth aspect, it is best not to raise the backward bias voltage Vr too much. In other words, as described in the second aspect, it is preferable for the backward bias voltage to be about ½ of, or less than ½ of, the withstand voltage of the organic layer.

Thus, it is preferable to realize the value of Xa by setting the backward bias voltage low and thinning the thickness Da of the upper electrodes to be 100 nm or less. Setting the thickness Da to be 100 nm or less was determined by measuring the scattered form of the upper electrodes with laser irradiation at the time of self-repair and investigating the thickness Da where the scattered form was a small and effectively electrically open form.

In an eighth aspect of the invention, when the backward bias voltage is represented as Vr, the thickness of the organic layer is represented as Dy, and the ratio Vr/Dy between Vr and Dy is represented as Ya, Ya is 1.2×10⁶ V/cm or greater and 2.2×10⁶ V/cm or less.

When the value of the ratio Ya is small, this indicates a case where the thickness Dy of the organic layer is thick when considered with the same backward bias voltage, and when the value of the ratio Ya is large, this indicates a case where the thickness Dy of the organic layer is thin. When the organic layer is too thick, it is difficult for self-repair to occur because it is difficult for the organic layer to scatter. Conversely, when the organic layer is too thin, an even thickness of the organic layer cannot be realized due to the effect of the unevenness and the like of the lower electrode. Thus, the organic layer ends up being scattered too much and triggers a remarkable drop in display quality, which is not preferable.

With respect to this point, self-repair can be more appropriately conducted by setting the ratio Vr/Dy between the backward bias voltage Vr and the organic layer thickness Dy to be 1.2×10⁶ V/cm or greater and 2.2×10⁶ V/cm or less (see FIG. 8), which is preferable.

In a ninth aspect of the invention, when the backward bias voltage is represented as Vr, the thickness of the organic layer excluding a conductive organic film is represented as Dy′, and the ratio Vr/Dy′ between Vr and Dy′ is represented as Ya′, Ya′ is 1.4×10⁶ V/cm or greater and 2.4×10⁶ V/cm or less.

In a tenth aspect of the invention, the pixels are sealed with a gas including a gas that increases susceptibility to burn at 0.5% or more.

It is preferable to use a gas that increases susceptibility to burn, such as oxygen, in order to effectively induce self-repair. According to this, electrical opening can be more reliably conducted as a result of not only the scattering of the upper electrode but also the oxidizing action (insulation) of the upper electrode.

In an eleventh aspect of the invention, an average surface roughness Ra is 2 nm or less as the surface roughness of the lower electrodes.

When the surface of the lower electrode is too rough, the distance between the lower and upper electrodes becomes too small locally. As a result, drawbacks easily arise, such as the withstand voltage of the organic layer also dropping, self-repair being generated too much, and breakage of the upper electrode. With respect to this point, these problems can be easily avoided by setting the average surface roughness Ra of the lower electrode to be 2 nm or less, which is preferable.

A twelfth aspect of the invention is a repair method of an organic EL device including pixels disposed with an organic layer including a light-emitting layer between lower electrodes and upper electrodes, wherein the pixels are made to repair themselves by applying a backward bias voltage equal to or less than the withstand voltage of the organic layer in a voltage application condition at the time of use.

According to this, a repair method that can exhibit the same effects as those of the invention of the first aspect can be provided.

In a thirteenth aspect of the invention, the withstand voltage when the organic EL device is driven for 1 minute or less in the voltage application condition at the time of use is used as the withstand voltage of the organic layer.

In the repair method of the twelfth aspect also, as in the invention of the thirteenth aspect, the initial withstand voltage can be the withstand voltage when the organic EL device is driven for 1 minute or less in the voltage application condition at the time of use.

In a fourteenth aspect of the invention, a voltage that is ½ of, or less than ½ of, the withstand voltage of the organic layer is used as the backward bias voltage.

According to this, a repair method that can exhibit the same effects as those of the invention of the third aspect can be provided.

In a fifteenth aspect of the invention, an organic EL device is used where, when the withstand voltage of the organic layer is expressed as an electric field intensity per unit thickness of the organic layer, the electric field intensity is 3×10⁶ V/cm or greater.

According to this, a repair method that can exhibit the same effects as those of the invention of the fourth aspect can be provided.

In a sixteenth aspect of the invention, an organic EL device is used where, when the withstand voltage of the organic layer is expressed as an electric field intensity per unit thickness of the organic layer, the electric field intensity is 3.4×10⁶ V/cm or greater excluding a conductive organic film from the organic layer in a case where the electric field intensity is calculated.

According to this, a repair method that can exhibit the same effects as those of the invention of the fifth aspect can be provided.

In a seventeenth aspect of the invention, when the backward bias voltage is represented as Vr, the thickness of the upper electrodes is represented as Da, and the ratio Vr/Da between Vr and Da is represented as Xa, Xa is 2.2×10⁶ V/cm or greater.

According to this, a repair method that can exhibit the same effects as those of the invention of the sixth aspect can be provided.

In an eighteenth aspect of the invention, Xa is 2.2×10⁶ V/cm or greater as a result of thinning the thickness Da of the upper electrodes to 100 nm or less.

According to this, a repair method that can exhibit the same effects as those of the invention of the seventh aspect can be provided.

In a nineteenth aspect of the invention, when the backward bias voltage is represented as Vr, the thickness of the organic layer is represented as Dy, and the ratio Vr/Dy between Vr and Dy is represented as Ya, Ya is 1.2×10⁶ V/cm or greater and 2.2×10⁶ V/cm or less.

According to this, a repair method that can exhibit the same effects as those of the invention of the eighth aspect can be provided.

In a twentieth aspect of the invention, when the backward bias voltage is represented as Vr, the thickness of the organic layer excluding a conductive organic film is represented as Dy′, and the ratio Vr/Dy′ between Vr and Dy′ is represented as Ya′, Ya′ is 1.4×10⁶ V/cm or greater and 2.4×10⁶ V/cm or less.

According to this, a repair method that can exhibit the same effects as those of the invention of the ninth aspect can be provided.

In a twenty-first aspect of the invention, self-repair is conducted in a state where the pixels are sealed with a gas including a gas that increases susceptibility to burn at 0.5% or more.

According to this, a repair method that can exhibit the same effects as those of the invention of the tenth aspect can be provided.

In a twenty-second aspect of the invention, a panel is used where an average surface roughness Ra is 2 nm or less as the surface roughness of the lower electrodes.

According to this, a repair method that can exhibit the same effects as those of the invention of the eleventh aspect can be provided.

In order to achieve the second object of the invention, the present inventors understood as a result of their extensive research that a self-repair effect can also be effectively realized by devoting attention to the withstand voltage of an organic layer and devising a resin protective film configuration when a backward bias voltage is applied with the objective of conducting self-repair.

When the backward bias voltage is raised in this manner, part or all of the upper electrodes in the pixels is scattered when there is no protective layer. The value of the backward bias voltage at this time is defined as the withstand voltage of the organic layer. According to this method, a substantially constant value is obtained as the withstand voltage of the organic layer in the voltage application condition at the time of use.

Namely, a twenty-second aspect of the invention is an organic EL display device where pixels that comprise lower electrodes, an organic layer including a light-emitting layer and upper electrodes being successively laminated are disposed and where a resin protective film comprising a resin is disposed on the upper electrodes so as to cover the pixels, wherein the resin protective film includes oxygen as a constituent element, and a backward bias voltage equal to or less than the withstand voltage of the organic layer in a voltage application condition at the time of use is applied, whereby the resin protective film decomposes and releases a low molecular weight substance including oxygen when the lower and upper electrodes short-circuit.

Because the withstand voltage drops at defective portions of the pixels, the lower and upper electrodes short-circuit due to the backward bias voltage equal to or less than the withstand voltage of the organic layer. In this case, because the resin protective film is decomposed by heat or the like generated by the short-circuiting, the upper electrodes and the organic layer positioned below the resin protective film also can scatter.

Additionally, the portions of the upper electrodes that have ruptured due to the scattering are covered and oxidized by a low molecular weight substance including oxygen released from the decomposed resin protective film, whereby part of the resin enters the upper electrodes so that the upper electrodes become electrically insulated.

As a result, the space between the lower and upper electrodes becomes electrically open at the defective portion where the upper electrodes have scattered, so that the defect does not spread any further. In other words, although a partial defect remains in the pixel, the withstand voltage of the pixel is recovered and the pixel is able to emit light. In this manner, self-repair is realized.

Thus, according to the invention, short-circuited portions of the lower and upper electrodes can be appropriately self-repaired in the organic EL display device where a resin protective film is disposed on the upper electrodes so as to cover the pixels.

Here, a silicon resin or a fluororesin can be used as the resin protective film.

In a twenty-third aspect of the invention, an inorganic protective film comprising inorganic matter is intervened between the resin protective film and the upper electrodes, and the inorganic protective film is formed by atomic layer epitaxy and the film thickness thereof is 200 nm or less.

At the time the resin protective film is formed, sometimes a solvent, low molecular weight organic matter, water and oxygen escape from the resin protective film, and these damage the organic layer of the base.

In such a case, according to the invention, the organic layer can be shielded from damaging substances by the inorganic protective film intervened between the pixels and the resin protective film. Of course, the inorganic protective film becomes unnecessary in a case where there is no potential for the organic layer to be damaged at the time the resin protective film is formed.

Also, the scattering of the upper electrodes and the decomposition of the resin protective film are hindered when the inorganic protective film is too thick. Thus, according to the investigations of the present inventors, it is preferable for the film thickness of the inorganic resin film to be thinned to 200 nm or less. Also, in order to appropriately form such a thin inorganic protective layer, atomic layer epitaxy, whose coverage is excellent in comparison to sputtering and vapor deposition, is preferable.

Also, in a twenty-fourth aspect of the invention, a gas-trapping getter is inserted between the upper electrodes and the resin protective film.

According to this, oxygen that is transmitted through the resin protective film from the outside can be trapped by the gas-trapping getter. Thus, damage to the organic layer can be further reduced, which is preferable.

Also, in a twenty-fifth aspect of the invention, a laminate film comprising metal foil or a laminate sheet formed by adhering together a metal film and resin films is disposed on the resin protective film, and the pixels and the resin protective film are shielded from outside air by the laminate film.

Also, in a twenty-sixth aspect of the invention, a desiccant is mixed into the resin protective film,

According to the invention of the twenty-fifth and twenty-sixth aspects, the organic layer can be more reliably protected from oxygen and water from the outside, which is preferable.

Further, when the ratio Vr/Dy described above is converted using the thickness Dy′ of the organic layer excluding the conductive organic film, this falls within the range of the invention.

It should be noted that the reference numerals in brackets in the above-described means are an example representing the corresponding relation with specific means described in the embodiments discussed later.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic cross-sectional diagram of an organic EL display device pertaining to a first embodiment of the invention;

FIG. 2 is a diagram showing an example of the schematic plan configuration of the organic EL device shown in FIG. 1;

FIG. 3 is a diagram showing an example of a drive waveform serving as a voltage application condition at the time of use in the organic EL device;

FIG. 4 is a graph showing a method where a reverse bias voltage is raised in order to determine the withstand voltage of an organic layer;

FIG. 5 is a graph showing an example of withstand voltage distribution according to results where the withstand voltage of the organic layer was investigated in regard to plural pixels;

FIGS. 6A and 6B are cross-sectional diagrams schematically showing an example of self-repair according to the first embodiment;

FIG. 7 is a graph showing results where the relation between a ratio Vr/Da of a reverse bias voltage Vr to an upper electrode thickness Da and a short circuit rate of upper and lower electrodes was investigated;

FIG. 8 is a graph showing results where the relation between a ratio Vr/Dy of the reverse bias voltage Vr to an organic layer thickness Dy and the short circuit rate of the upper and lower electrodes was investigated;

FIG. 9 is a graph showing the relation between the thickness of the organic layer and the average withstand voltage of the organic layer that the present inventors investigated;

FIG. 10 is a schematic cross-sectional diagram of an organic EL display device pertaining to a second embodiment of the invention;

FIG. 11 is a schematic cross-sectional diagram of an organic EL display device pertaining to a third embodiment of the invention; and

FIG. 12 is a schematic cross-sectional diagram of an organic EL display device serving as a modified example of the third embodiment.

FIG. 13 is a schematic cross-sectional diagram of an organic EL device pertaining to a fourth embodiment of the invention;

FIGS. 14A and 14B are cross-sectional diagrams schematically showing an example of self-repair according to the fourth embodiment;

FIG. 15 is a chart showing respective properties of the organic EL devices used in specific examples of the fourth embodiment; and

FIG. 16 is a graph showing the relation between the thickness of the organic layer and the average withstand voltage of the organic layer that the present inventors investigated.

### DESCRIPTION OF THE PREFERRED EMBODIMENT

The present invention will be described below with reference to embodiments shown in the drawings. In the following embodiments, the same reference numerals are given to the same portions in the drawings.

(First Embodiment)

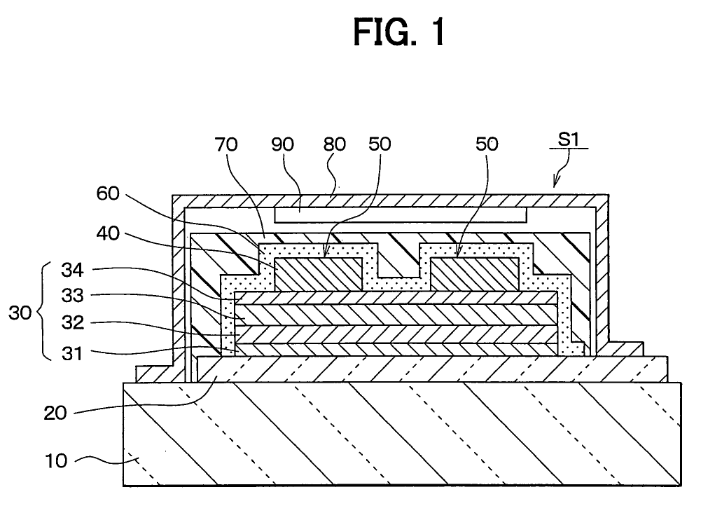

FIG. 1 is a diagram showing the schematic cross-sectional configuration of an organic EL display device S1 pertaining to a first preferred embodiment. The organic EL display device S1 is formed by a lower electrode 20, an organic layer 30 including a light-emitting layer 33, and upper electrodes 40 being successively laminated on an insulating substrate 10 of glass or resin.

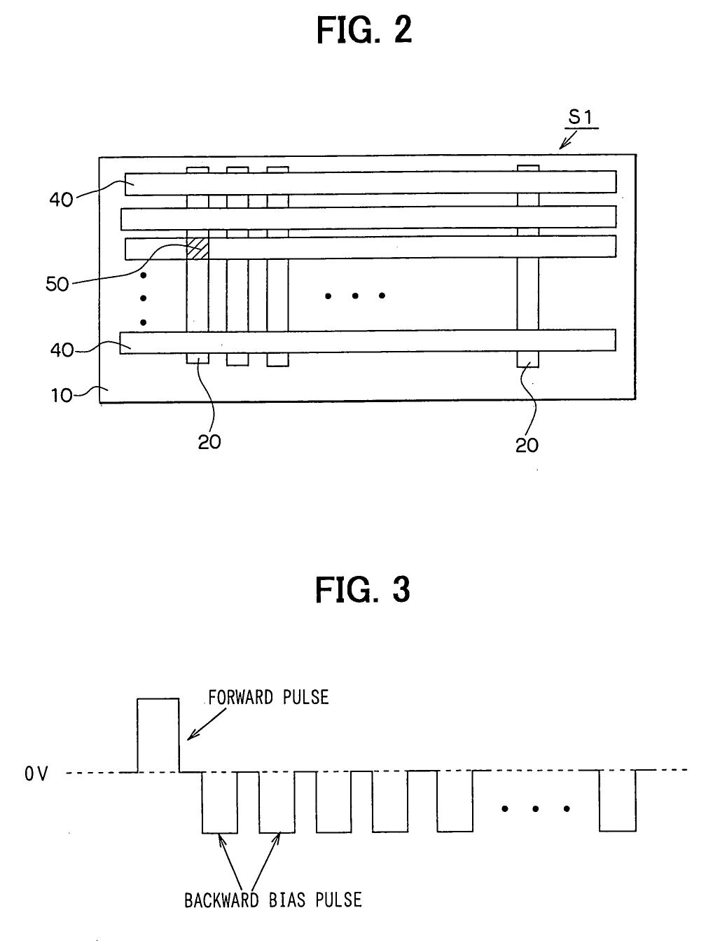

Here, the lower and upper electrodes 20 and 40 and the organic layer 30 in regions where the lower electrode 20 and the upper electrodes 40 are superposed are formed as pixels 50. Here, FIG. 2 is a diagram showing an example of the schematic plan configuration of the organic EL display device S1 shown in FIG. 1.

In the present example, as shown in FIG. 2, the electrodes 20 and 40 form mutually intersecting stripes, and the portions at which the striped electrodes 20 and 40 intersect are the pixels 50. Additionally, each pixel 50 has a size of a 0.3 mm angle so that the pixels 50 configure a 256×64 dot matrix.

The lower electrode 20 comprises optically transparent ITO (Indium Tin Oxide). Also, in the present embodiment, the organic layer 30 is formed by a positive-hole injection layer 31 comprising a positive-hole injection organic material or the like, a positive-hole carrier layer 32 comprising a positive-hole carrier organic material or the like, a light-emitting layer 33 comprising a material where a light-emitting dye is included in a positive-hole carrier or an electron carrier organic material, and an electron carrier layer 34 comprising an electron carrier organic material being successively laminated.

Also, the upper electrodes 40 comprise a metal film such as Al. A material used, or a material having the potential to be used, in an ordinary organic EL display device can be applied to the layers configuring the pixels 50.

In the present organic EL display device S1 having this pixel configuration, the lower electrodes 20 serve as anodes and the upper electrodes 40 serve as cathodes, and driving is conducted by applying voltages between the lower and upper electrodes 20 and 40. In this case, a forward bias voltage is applied to the pixels 50 at the time light is to be emitted so that light is emitted, and a backward bias voltage is applied to the pixels 50 at the time light is not to be emitted in order to curb light emission resulting from cross talk or the like.

Specifically, in the dot matrix type organic EL display device S1 of the present example, a pulse voltage of a drive waveform having a predetermined duty ratio and a predetermined pulse width such as shown in FIG. 3 is applied with respect to one pixel 50. The light-emitting layer 33 emits light when the forward bias voltage (forward pulse) is applied thereto, and the light-emitting layer 33 does not emit light when the backward bias voltage (backward bias pulse) is applied thereto.

Moreover, as shown in FIG. 1, in the present organic EL display device S1, an inorganic protective film 60 and a resin protective film 70 are successively laminated on the upper electrodes 40 so as to cover the pixels 50. These protective films 60 and 70 cover, at the upper portions of the upper electrodes 40 and the upper portion of the organic layer 30 where the upper electrodes 40 are not formed, a wider range than the region where the organic layer 30 is formed and protect the organic layer 30 that is the base.

The inorganic protective film 60 comprises a material selected from Al₂O₃, SiN, SiNO, ZnS—SiO₂, SiO₂ and LiO, and is formed by atomic layer epitaxy (ALE), which is described in JP-A-2001-284042, or by sputtering or vapor deposition.

The film thickness of the inorganic protective film 60 is 200 nm or less and preferably several tens of nm, to form an inorganic protective film that is considerably thinner than conventional inorganic protective films having a thickness of several μm. It is preferable to use a film of Al₂O₃ formed using atomic layer epitaxy, which has excellent coverage, as the thin inorganic protective film 60.

The resin protective film 70 includes oxygen as a constituent element. When the lower electrode 20 and the upper electrodes 40 have short-circuited due to a backward bias voltage equal to or less than the withstand voltage of the organic layer 30 in a voltage application condition at the time of use such as shown in FIG. 3 being applied thereto, the resin protective film 70 decomposes and releases a low molecular weight substance including the oxygen.

A silicon resin or a fluororesin can be used as the resin protective film 70, and the resin protective film 70 can be formed by a method where the resin is coated and hardened. The film thickness thereof can be several tenths of mm, e.g., 0.01 mm to 0.5 mm.

In a case where a silicon resin is used as the resin protective film 70, silicon rubber, silicon gel or silicon oil can be used. Also, in a case where a fluororesin is used, fluorine rubber, fluorine gel or fluorine oil can be used.

For example, the silicon resin includes siloxane in the resin, is decomposed by heat when the lower and upper electrodes 20 and 40 short-circuit, and releases the siloxane as the low molecular weight substance including oxygen.

The inorganic protective film 60 below the resin protective film 70 is for protecting the organic layer 30 from a solvent and low molecular weight organic matter generated at the time the resin protective film 70 is formed, water, and substances that damage the organic layer 30 such as oxygen.

In other words, the organic layer 30 is shielded from the above damaging substances by the inorganic protective film 60 intervened between the pixels 50 and the resin protective film 70. Of course, the inorganic protective film 60 is not necessary in cases where substances that damage the organic layer 30 are not generated at the time the resin protective film 70 is formed or where, if such substances are generated, the damage to the organic layer 30 does not become a problem.

Also, a case 80 that contains the resin protective film 70 and the layers 20 to 60 therebelow and shields the same from outside air is disposed on the resin protective film 70. The case 80 comprises a metal or ceramic and is fixed by adhesion to a peripheral portion of the substrate 10.

Additionally, in the first preferred embodiment, a desiccant 90 is disposed inside the case 80. The desiccant 90 is for absorbing water penetrating from the portion where the case 80 and the substrate 10 are adhered. For example, barium oxide (BaO) or calcium oxide (CaO) can be used for the desiccant 90.

Also, the inside of the case 80 is filled with nitrogen gas or inert gas as the injected gas. In this manner, the inside of the case 80 becomes a dry atmosphere so that water can be prevented from penetrating the organic layer 30.

The organic EL display device S1 can be manufactured in the following manner. First, the layers 20 to 40 are successively formed on the substrate 10 using sputtering or vacuum deposition. Next, the inorganic protective film 60 is formed using atomic layer epitaxy (ALE), sputtering or vapor deposition.

With respect to the formation of the inorganic protective film 60, the inorganic protective film 60 is formed using a mask made of quartz glass, whereby the region where the inorganic protective film 60 is formed is set so that terminal portions connected to external circuits in the lower electrodes (anodes) 20 and the upper electrodes (cathodes) 40 are not exposed.

Next, the resin protective film 70 is coated on the inorganic protective film 60 with a dispenser or the like and hardened by heating and drying. The formation of the resin protective film 70 is conducted in an environment where water and an atmosphere of oxygen are controlled, so that the penetration of water and oxygen into the resin protective film 70 from the outside is controlled as much as possible.

Then, the case 80 on which the desiccant 90 is fixed is adhered to the substrate 10 in a dry nitrogen atmosphere or an inert gas atmosphere, and the pixels 50 and the protective layers 60 and 70 on the substrate 10 are air proofed and sealed by the case 80. In this manner, the organic EL display device S1 is manufactured.

(Self-Repairing Action)

The drive waveform shown in FIG. 3 is a voltage application condition at the time of use in the organic EL device S1. In the present embodiment, the pixels 50 are capable of self-repair when a backward bias voltage equal to or less than the withstand voltage (or dielectric strength) of the organic layer 30 in this voltage application condition at the time of use is applied.

The withstand voltage of the organic layer 30 is determined on the basis of a voltage measured in a state that the pulse width is the same as that defined by the duty ratio and frequency when the device is actually driven. In other words, in the drive waveform shown in FIG. 3, a forward current is held constant (i.e., light-emitting luminance is substantially constant) and the backward bias voltage where light is not emitted serves as the withstand voltage while the magnitude of the backward bias voltage is increased.

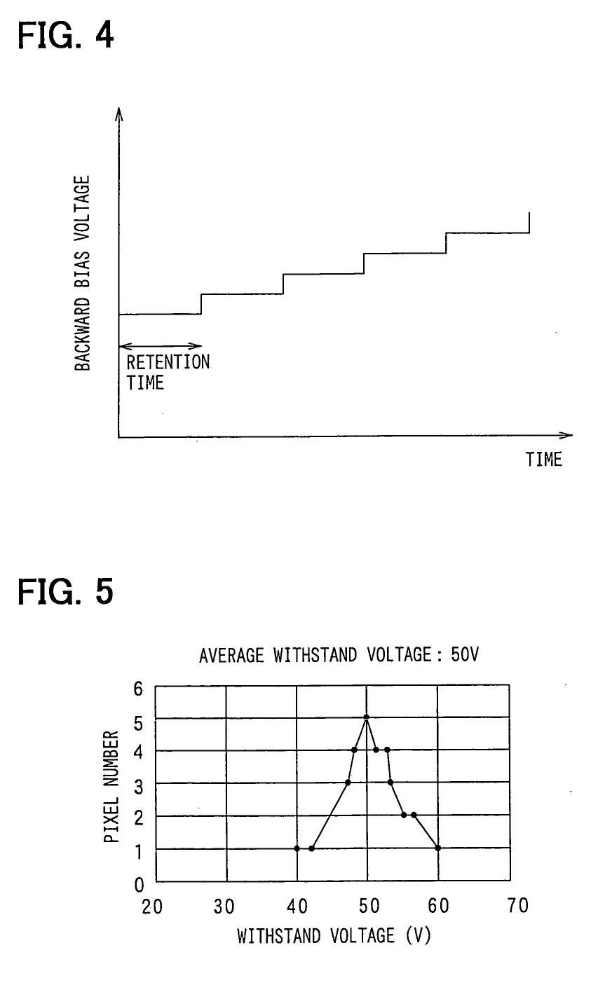

Here, as shown in FIG. 4, a method where the backward bias voltage is raised in increments of several volts while the retention time per voltage is set to be 5 seconds or more and 1 minute or less is used as a way of changing the backward bias voltage. Also, at this time, a device of an element configuration where the protective layers 60 and 70 are not disposed with respect to FIG. 1 is used.

When the backward bias voltage is raised in this manner, part or all of the upper electrodes 40 in the pixels 50 is scattered. The value of the backward bias voltage when this scattering occurs is defined as the withstand voltage of the organic layer 30.

According to this method, a substantially constant value is obtained as the withstand voltage of the organic layer 30 in the voltage application condition at the time of use. Although they are not limited, in the present example, the forward bias voltage is kept at a constant of 10 V, and the backward bias voltage is raised in increments of 1 V from 20 V while the retention time is set at 5 seconds, whereby the withstand voltage of the organic layer 30 can be determined.

Moreover, because the organic EL display device S1 of the present example includes plural pixels 50, as shown in FIG. 2, the withstand voltages of the organic layers 30 in the pixels 50 have a certain constant distribution.

Specifically, in the present example, as a result of investigating the withstand voltages of the organic layers 30 in regard to the plural pixels 50, they have the distribution shown in FIG. 5. Additionally, the withstand voltages of the organic layers 30 in the present example had an average value—i.e., an average withstand voltage (in FIG. 5, 50 V).

In this manner, in the present embodiment, the organic EL display device S1 where the withstand voltage of the organic layer 30 in the voltage application condition at the time of use is defined adopts a unique configuration where the resin protective film 70 decomposes and releases a low molecular weight substance including oxygen when the lower and upper electrodes 20 and 40 short-circuit due to a backward bias voltage equal to or less than the withstand voltage of the organic layer 30 being applied thereto.

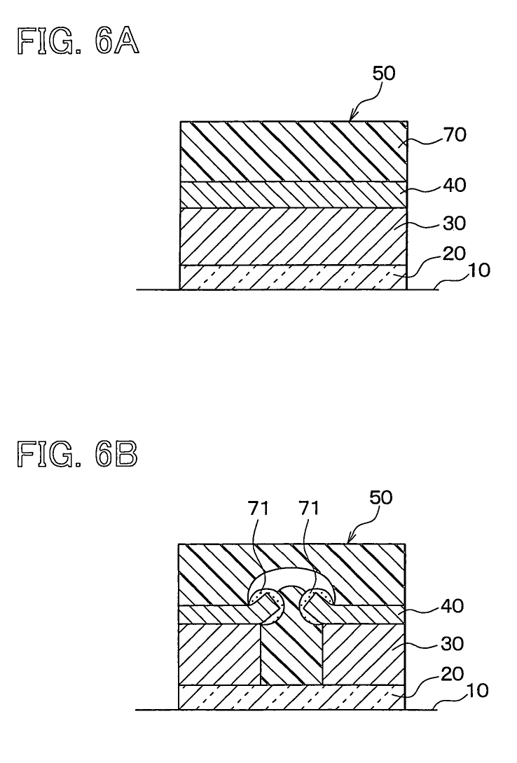

By adopting this unique configuration, self-repair of defective portions of the pixels 50 is possible. This self-repair will be described with reference to FIGS. 6A and 6B.

FIGS. 6A and 6B are cross-sectional diagrams schematically showing an example of self-repair according to the present embodiment. FIG. 6A shows the state of a pixel 50 before self-repair and FIG. 6B shows the state of the same pixel 50 after self-repair. It should be noted that the inorganic protective film 60 is omitted.

Withstand voltage drops in the defective portion of the pixel 50. Thus, the lower and upper electrodes 20 and 40 short-circuit due to the backward bias voltage equal to or less than the withstand voltage of the organic layer 30. In this case, as shown in FIG. 6B, the resin protective film 70 is decomposed by heat generated by the short-circuit, whereby the thin inorganic protective film 60, the upper electrode 40 and the organic layer 30 positioned below the resin protective film 70 can also scatter.

Then, the portions of the upper electrode 40 that have ruptured and where the scattering has arisen are covered and oxidized by a low molecular weight substance 71 including oxygen released from the decomposed resin protective film 70, whereby the upper electrode 40 becomes electrically insulated. Also, the portion where the organic layer 30 has scattered is filled with part of the decomposed resin protective film 70. This condition was confirmed by observing the cross section with a microscope.

As a result of this phenomenon occurring, the space between the lower and upper electrodes 20 and 40 becomes electrically open at the defective portion where the upper electrode 40 has scattered, so that the defect does not spread any further. In other words, although a partial defect remains in the pixel 50, the withstand voltage of the pixel 50 is recovered and the pixel 50 is able to emit light. In this manner, self-repair is realized.

Thus, according to the present embodiment, short-circuited portions of the lower and upper electrodes 20 and 40 can be appropriately self-repaired in an organic EL display device where a resin protective film is disposed on the upper electrodes 40 so as to cover the pixels 50.

In a case where, for example, a silicon resin is used as the resin protective film 70, the action of the resin protective film 70 is effectively realized with siloxane serving as the low molecular weight substance 71 including oxygen. More particularly, the portion of the upper electrode 40 that has ruptured due to scattering as a result of heat when a short circuit has occurred is oxidized by the oxygen in the siloxane, and part of the resin enters the upper electrode so that short-circuiting of the lower and upper electrodes 20 and 40 is prevented.

Here, as described above, because the inorganic protective film 60 intervened between the resin protective film 70 and the upper electrode 40 is disposed as needed, the film thickness of the inorganic protective film 60 is 200 nm or less and preferably several tens of nm in a case where the inorganic protective film 60 is intervened.

This is because the scattering of the upper electrode 40 and the decomposition of the resin protective film are hindered when the inorganic protective film 60 is too thick. It is also preferable to use a film of Al₂O₃ formed using atomic layer epitaxy, whose coverage is excellent, as the thin inorganic protective film 60.

Inorganic protective films in the protective films of conventional organic EL display devices such as the one described in JP-A-2000-223264 have been several μm, which is thick. Therefore, it has been impossible for the upper electrodes to sufficiently scatter and self-repair has been difficult.

Also, the value of the backward bias voltage for self-repair can be set to an appropriate magnitude using, as a guide, the withstand voltage of the organic layer 30 in the voltage application condition at the time of use.

More particularly, with respect to the voltages applied to the pixels 50 during use, the backward bias voltage applied at the time light is not to be emitted is set to a magnitude that is equal to or less than the withstand voltage of the organic layer 30, whereby setting of an excessive backward bias voltage where all of the upper electrodes 40 end up scattering can be prevented.

Also, because the withstand voltage of the organic layer 30 is used as a guide, the magnitude of the backward bias voltage is allowed as far as a magnitude that is equal to or less than the withstand voltage. Thus, a case where the backward bias voltage is too small and self-repair becomes insufficient can be prevented.

Also, although it was described with reference to FIG. 4, in the present embodiment, the withstand voltage of the organic layer 30 is the withstand voltage when the device is driven for 1 minute or less in the voltage application condition at the time of use. In other words, this means that the withstand voltage was determined using 1 minute or less as the retention time in FIG. 4.

It is clear that, because the withstand voltage of the organic layer 30 drops with the lapse of use time, it is preferable to use the withstand voltage at the early stage of use in order to exhibit effects over a long period of time from the early stage of use, i.e., over the entire time of use. This initial withstand voltage can be the withstand voltage when the organic EL display device is driven for 1 minute or less in the voltage application condition at the time of use.

(Preferred Means)

Next, examples of preferable means for the first preferred embodiment will be described. It is preferable for the organic EL display device S1 of the present embodiment to have a relationship where the backward bias voltage in the voltage application condition at the time of use is ½ of, or less than ½ of, the withstand voltage of the organic layer 30.

Even if the backward bias voltage is equal to or less than the withstand voltage of the organic layer 30, there are cases where, depending on the element structure, the upper electrodes 40 of the overall pixels 50 are scattered. With respect to this point, by setting the backward bias voltage to be ½ of, or less than ½ of, the withstand voltage of the organic layer 30, it is possible to reliably achieve scattering of the upper electrodes 40 of only sites that one wishes to have self-repaired, regardless of the element structure.

Moreover, as described above, because the withstand voltages of the organic layers 30 have a distribution resulting from structural variations between the plural pixels 50 and variations per structural lot, the withstand voltages of the organic layers 30 are actually investigated in regard to the plural pixels 50 and the average withstand voltage thereof is used.

With respect thereto, by lowly holding the backward bias voltage to be ½ of, or less than ½ of, the withstand voltage of the organic layer 30, there is the advantage that it is easy to prevent the upper electrodes 40 from scattering too much in pixels 50 removed from the average.

Also, in the organic EL display device S1, it is preferable to ensure that, when the withstanding voltage of the organic layer 30 is expressed as an electric field intensity per unit thickness of the organic layer 30, the electric field intensity is 3×10⁶ V/cm or greater.

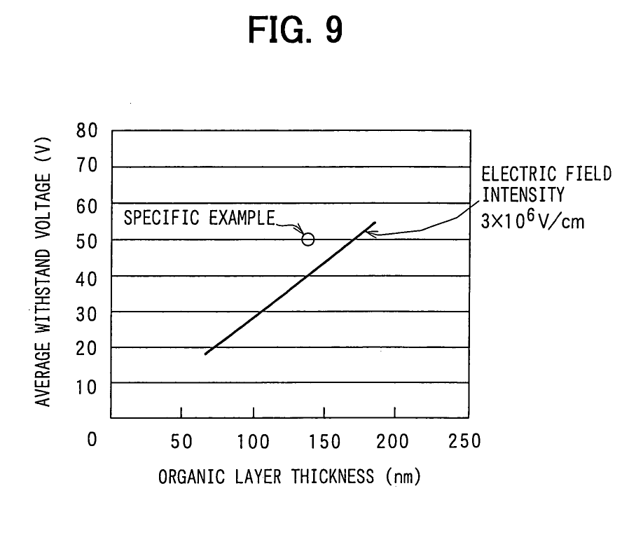

According to the investigations of the present inventors, it was understood that, in the organic EL display device, the withstand voltage of the organic layer 30 can be defined by the total thickness thereof regardless of the type of organic material (see FIG. 9, which will be discussed later). Additionally, a device where the electric field intensity is 3×10⁶ V/cm or greater can be used as the organic EL display device S1. According to this, the effects of the present embodiment can be effectively exhibited.

More preferably, the electric field intensity is 3.4×10⁶ V/cm or greater excluding a conductive organic film from the organic layer 30 when the electric field intensity is calculated. For example, in a case where the positive-hole injection layer 31 comprises copper phthalocyanine, the positive-hole injection layer 31 becomes the conductive organic film in the organic layer 30.

Additionally, in the organic EL display device, in a case where the thickness of the organic film using a porphyrin conductive material typified by copper phthalocyanine differs by a compared panel, particularly as the thickness thereof becomes thicker to about 30 nm or more, sometimes the electric field intensity is not constant.

This is because resistance is sufficiently small and the electric field does not participate much in comparison to the other organic films in the organic layer 30. Thus, it is more preferable to exclude the conductive organic film from the organic layer in order to more precisely compare electric field intensity.

When the electric field intensity defining the withstand voltage of the organic layer 30 is reassessed in a case where the conductive organic film is excluded in this manner, it becomes 3.4×10⁶ V/cm or greater. Additionally, the effects of the present embodiment can be effectively exhibited according to this electric field intensity also.

Also, in the organic EL display device, when the backward bias voltage is represented as Vr, the thickness of each upper electrode 40 is represented as Da and the ratio Vr/Da between Vr and Da is represented as Xa, it is preferable for the value of Xa (=Vr/Da) to be 2.2×10⁶ V/cm or greater.

When the backward bias voltage is too small and the upper electrodes 40 are too thick, it is difficult for the upper electrodes 40 to scatter and self-repair. In other words, when the value of Xa (=Vr/Da) is too small, self-repair is difficult.

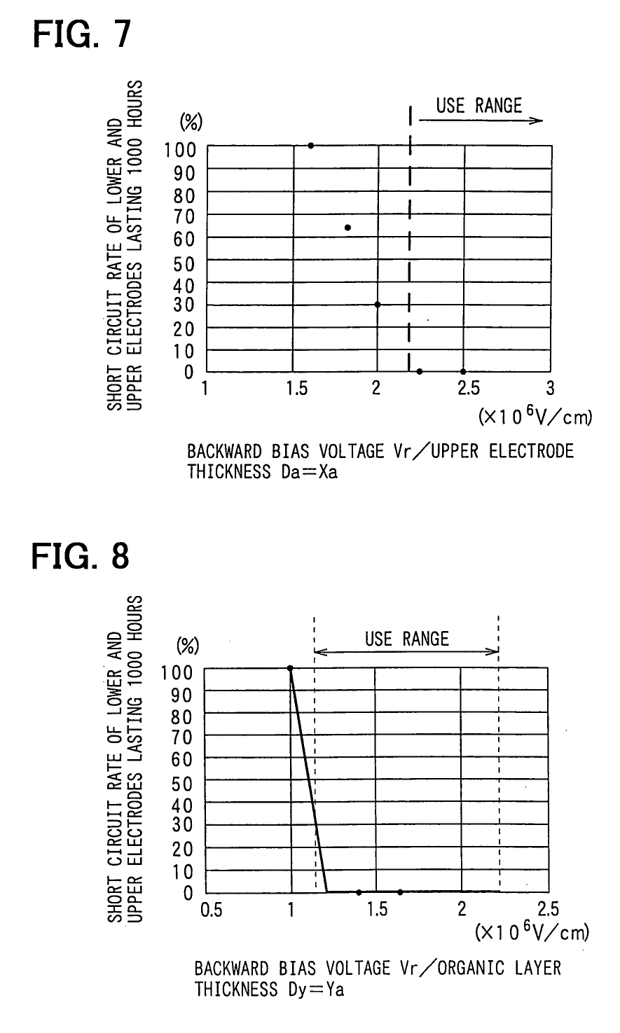

Thus, the present inventors investigated the relation ship between Vr/Da=Xa and the short circuit rate of the lower and upper electrodes 20 and 40 in the organic EL display device S1. The results are shown in FIG. 7.

In FIG. 7, the short circuit rate of the lower and upper electrodes represents the rate of occurrence of portions (e.g., line defects, etc.) where the short-circuited portions of the lower and upper electrodes 20 and 40 were not self-repaired after the lasting time as the use time was 1000 hours, i.e., after the organic EL display device had been driven for 1000 hours.

As shown in FIG. 7, in a case where the ratio Vr/Da=Xa is less than 2.2×10⁶ V/cm, the upper electrodes 40 are too thick, the backward bias voltage is too small, the scattering of the upper electrodes 40 is insufficient and self-repair is difficult. However, by setting the ratio Vr/Da=Xa to be 2.2×10⁶ V/cm or greater, self-repair can be appropriately conducted.

Moreover, it is preferable to ensure that the ratio Xa (=Vr/Da) is 2.2×10⁶ V/cm or greater by thinning the thickness Da of the upper electrodes 40 to 100 nm or less.

This is because it is best not to raise the backward bias voltage Vr too much as a means of realizing the value of the ratio Xa. More particularly, as described above, this is because it is preferable to hold, as much as possible, the backward bias voltage Vr to be ½ of, or less than ½ of, the withstand voltage of the organic layer 30.

Thus, it is preferable to realize the value of Xa by setting the backward bias voltage low and thinning the thickness Da of the upper electrodes 40 to 100 nm or less. Setting the thickness Da to 100 nm or less was determined by measuring the scattered form of the upper electrodes 40 with laser irradiation at the time of self-repair and investigating the thickness Da where the scattered form was a small and effectively electrically open form.

Also, in the organic EL display device S1 of the present embodiment, when the backward bias voltage is represented as Vr, the thickness of the organic layer 30 is represented as Dy, and the ratio Vr/Dy between Vr and Dy is represented as Ya, it is preferable for this ratio Ya to be 1.2×10⁶ V/cm or greater and 2.2×10⁶ V/cm or less.

When the value of the ratio Ya is small, this indicates a case where the thickness Dy of the organic layer 30 is thick when considered with the same backward bias voltage, and when the value of the ratio Ya is large, this indicates a case where the thickness Dy of the organic layer 30 is thin.

When the organic layer 30 is too thick, it is difficult for self-repair to occur because it is difficult for the organic layer 30 to scatter. Conversely, when the organic layer 30 is too thin, an even thickness of the organic layer 30 cannot be realized due to the affect of the unevenness and the like of the lower electrode 20. Thus, the organic layer 30 ends up being scattered too much and triggers a remarkable drop in display quality, which is not preferable.

Thus, the present inventors investigated the relationship between the ratio Vr/Da=Ya and the short circuit rate of the lower and upper electrodes 20 and 40 in the present organic EL display device S1. The results thereof are shown in FIG. 8.

In FIG. 8, the short circuit rate of the lower and upper electrodes is defined in the same manner as in FIG. 7. From FIG. 8, it will be understood that, in a case where the ratio Vr/Da=Ya is less than 1.2×10⁶ V/cm, the organic layer 30 is too thick, the backward bias voltage is too small, scattering of the organic layer 30 and the upper electrodes 40 is insufficient, and self-repair is difficult.

Conversely, in a case where the ratio Vr/Da=Ya is greater than 2.2×10⁶ V/cm, short-circuiting is prevented, but the organic layer 30 is too thin and the organic layer 30 ends up being scattered too much and triggers a remarkable drop in display quality, which is not preferable.

From the results of this investigation, it was understood that, by setting the ratio Vr/Da=Ya to be 1.2×10⁶ V/cm or greater and 2.2×10⁶ V/cm or less, self-repair can be appropriately conducted.

Also, when the backward bias voltage is represented as Vr, the thickness of the organic layer 30 excluding the conductive organic film is represented as Dy′, and the ratio Vr/Dy′ between Vr and Dy′ is represented as Ya′, it is preferable for this ratio Ya′ to be 1.4×10⁶ V/cm or greater and 2.4×10⁶ V/cm or less.

This is because, as described above, electric field intensity can be more precisely compared by using the thickness of the organic layer 30 excluding the conductive organic film. Additionally, the ratio Vr/Dy′=Ya′ can be easily derived by converting the ratio Vr/Da=Ya.

Next, although it is not limited, the present embodiment will be more specifically described with reference to the following specific example.

In the following specific example, characteristic values of the organic EL display device S1 represent a lower electrode surface roughness Ra (nm), an organic layer thickness Dy (nm), an upper electrode thickness Da, a backward bias voltage Vr (V), organic layer withstand voltage Vd (V), electric field intensity Vd/Dy (V/cm) and Vd/Dy′ of the withstand voltage of the organic layer, and the ratios Xa, Ya and Ya′.

(Specific Example of Self-Repair)

In the present example, the substrate 10 comprised a glass substrate, and the lower electrode (anode) 20 comprised an ITO film of a film thickness of about 150 nm formed by sputtering and was configured as a positive-hole injection electrode (i.e., an anode). Also, the surface of the lower electrode 20 was polished so that the average surface roughness Ra was equal to 1.2 nm.

The organic layer 30 of the present example was formed by vacuum deposition by pretreating the ITO surface with UV ozone and then placing the ITO in a vacuum chamber.

First, the positive-hole injection layer 31 was formed by forming a 15-nm film of copper phthalocyanine (CuPc), and the positive-hole carrier layer 32 was formed thereon by forming a film of a 50-nm film of alpha-naphthyl phenol benzene.

The light-emitting layer 33 was formed thereon by forming a 40-nm film of quinolinol aluminum doped with 1% coumarin, and the electron carrier layer 34 was formed by forming a 30-nm film of quinolinol aluminum. Moreover, the upper electrodes (cathodes) 40 were formed by laminating and vapor depositing 0.5 nm of LiF and 80 nm of Al. The upper electrode thickness Da was 80 nm. In this case, the color of the emitted light was green.

The inorganic protective film 60 was formed thereon by forming a film of Al₂O₃ with a thickness of about 60 nm using atomic layer epitaxy (ALE) described in paragraphs 28 to 31 of JP-A-2001-284042. Thus, it was ensured that the organic layer 30 was shielded from being penetrated by water from the outside or the low molecular weight organic matter and solvent from the resin at the time the resin protective film 70 of a later step was coated and dried.

Next, the resin protective film 70 comprising a silicon resin was formed on the inorganic protective film 60. Here, KE-1031 (trade name) manufactured by Shin-Etsu Chemical Co., Ltd. was used for the silicon resin. This silicon resin is a 2-liquid type comprising a desiccant and a base. These liquids were heated at 80° C. and deaerated in order to remove the water from the resin, and then they were mixed and coated.

The coating was conducted by a method where the liquids were automatically dripped using a dispenser in an environment where water and an oxygen atmosphere were controlled. After the liquids were coated, they were heated and dried for 2 hours in a vacuum. The film thickness of the resin protective film produced thereby was 0.01 mm to 0.5 mm.

Then, the workpiece up to this point was placed in a dry nitrogen atmosphere whose dew point was −70° C., 1% of oxygen was introduced as a gas to increase the susceptibility to burn, and then the workpiece was sealed using the case 80 having the desiccant 90. In this manner, the organic EL display device S1 of the present specific example was manufactured.

The withstand voltage Vd of the organic layer 30 in a case where the organic EL display device was driven at 120 Hz with a duty ratio of 1/64 was 50 V. The withstand voltage Vd of the organic layer 30 was determined in a state where the protective layers 60 and 70 were not formed.

It should be noted that the 50-V withstand voltage of the organic layer 30 of the present example corresponds to the average withstand voltage shown in FIG. 5. The withstand voltage of the organic layer 30 was 3.7×10⁶ V/cm at the electric field intensity Vd/Dy per unit thickness of the organic layer 30. Also, the electric field intensity Vd/Dy′ was 4.2×10⁶ V/cm when the thickness of the copper phthalocyanine (CuPc) of the positive-hole injection layer 31 that was the conductive organic film was excluded.

Driving was conducted to become a duty ratio of 1/64, and the forward pulse (forward bias voltage) was adjusted with a constant current drive so that the initial luminance was 200 cd/m². The voltage of the forward pulse at this time was about 10 V. A 20-V backward bias pulse was applied, as the backward bias voltage Vr, at the time other than that of the forward pulse.

At this time, the ratio Xa (=Vr/Da) was 2.5×10⁶ V/cm and Ya (=Vr/Dy) was 1.48×10⁶ V/cm. Also, Ya′ (=Vr/Dy′) was 1.7×10⁶ V/cm.

When the durability of the organic EL display device S1 was evaluated, it was confirmed that no drawbacks leading to short-circuiting of the lower and upper electrodes 20 and 40 such as line defects arose, even when the organic display device S1 was operated for 1000 hours or more at a high temperature of 80° C., and self-repair was appropriately conducted. Also, action such as the insulation of the upper electrodes 40 resulting from the resin protective film 70 such as shown in FIG. 6 was confirmed by microscopic observation.

Also, in the present specific example, as the withstand voltage of the organic layer 30, the electric field intensity Vd/Dy per unit thickness of the organic layer 30 was 3×10⁶ V/cm or greater. FIG. 9 is a diagram showing the relation between the thickness (nm) and the average withstand voltage (V) of the organic layer 30 that the present inventors investigated. The electric field intensity of the present specific example is also plotted.

As shown in FIG. 9, according to the investigation of the present inventors, in the organic EL display device, it was understood that the withstand voltage of the organic layer 30 can be defined by the total thickness thereof, regardless of the type of organic material. Additionally, the self-repairing effect was sufficiently exhibited in the present specific example where the electric field intensity was 3×10⁶ V/cm or greater.

(Second Embodiment)

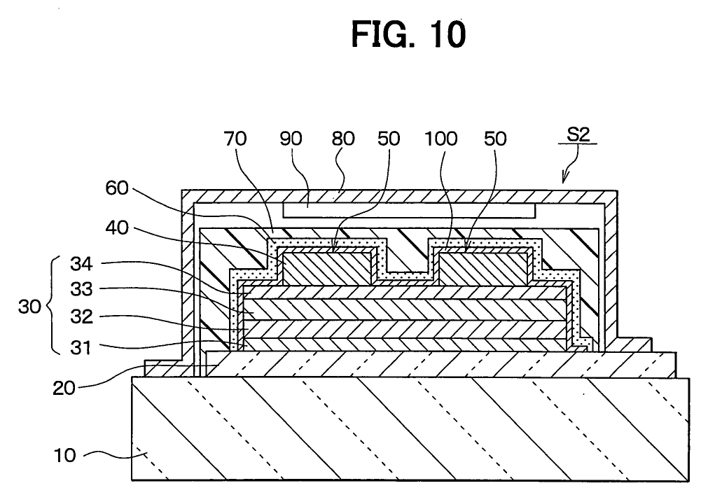

FIG. 10 is a diagram showing the schematic cross-sectional configuration of an organic EL display device S2 pertaining to a second preferred embodiment. The points of difference with the first embodiment will mainly be described.

In the second embodiment, a gas-trapping getter 100 is inserted and disposed between the upper electrodes 40 and the resin protective film 70 (in the present example, between the upper electrodes 40 and the inorganic protective film 60) in the organic EL display device shown in FIG. 1. The getter 100 can be formed by forming a 20-nm film of metal Ba on the upper electrodes 40 by vacuum deposition.

According to this, oxygen that is transmitted through the resin protective film 70 from the outside can be trapped by the gas-trapping getter 100. Thus, damage to the organic layer 30 can be further reduced, and there is the effect of preventing a drop in luminance.

(Third Embodiment)

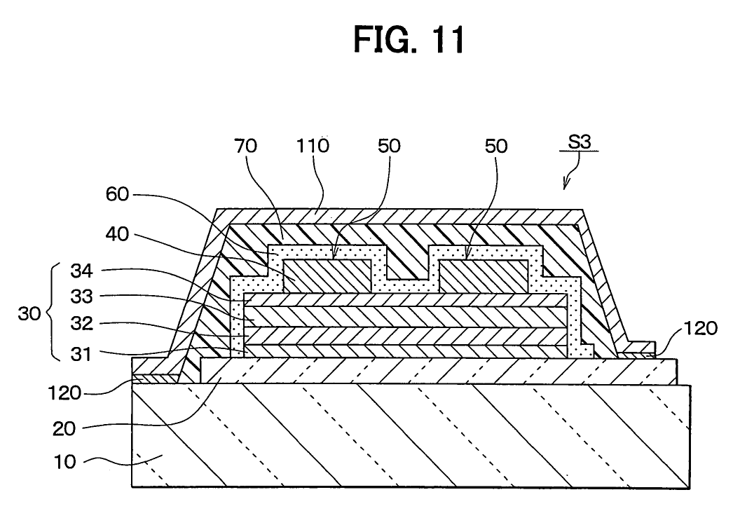

FIG. 11 is a diagram showing the schematic cross-sectional configuration of an organic EL display device S3 pertaining to a third preferred embodiment. The points of difference with the preceding embodiments will mainly be described.

In the third embodiment, a laminate film 110 is disposed on the resin protective film 70 in place of the case 80 with respect to the organic EL display device shown in FIG. 1. Additionally, the pixels 50 and the resin protective film 70 are shielded from outside air by the laminate film 110.

The laminate film 110 comprises metal foil or a laminate sheet formed by adhering together a metal film and a resin film. Specifically, a laminate formed by sandwiching Al foil between resin films can be used.

Because the laminate film 110 is deformable, it can be adhered to match the surface shape of the organic EL display device. Additionally, the laminate film 110 is fixed to the substrate 10 by, for example, a UV-curable adhesive 120.

Also, in the example shown in FIG. 11, the desiccant 90 is abolished in accompaniment with the abolishment of the case 80. Thus, here, a desiccant (not shown) is mixed into the resin protective film 70. CaH₂ or CaO can be used for the desiccant and mixed with and coated on the resin to form the resin protective film 70 including the desiccant.

According to the present example, the laminate film 110 is substituted for the case 80 whereby, similar to the instance where the case 80 is disposed, the organic layer 30 is more reliably protected from external water and oxygen. Moreover, by forming the resin protective film 70 including the desiccant, the effect is further raised.

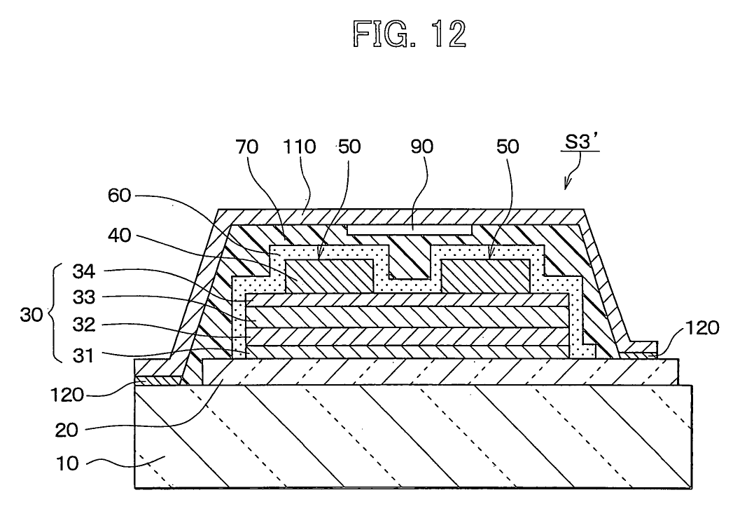

FIG. 12 is a diagram showing the schematic cross-sectional configuration of an organic EL display device S3′ serving as a modified example of the present embodiment. This example has a configuration where the desiccant 90 is adhered to the laminate film 110, without mixing the desiccant into the resin protective film 70. In this case also, the effects of the present embodiment can be similarly exhibited.

It should be noted that, in FIG. 1, an inorganic film and a resin film may be laminated on the resin protective film 70 and that these films may be substituted for the case 80.

Also, in place of the case 80, a platy cover plate may be disposed on the resin protective film 70, and the space between the cover plate and the substrate 10 may be filled with an adhesive. In this case, the case 80 becomes unnecessary because the filled adhesive seals the element.

In the present embodiment, the lower and upper electrodes in places having low withstand voltage were short-circuited in advance at a point in time prior to placing the organic EL display device on the market. However, even if the lower and upper electrodes short circuit at the time of use after the device has been placed on the market due to the above-mentioned mechanism, self-repair of those short-circuited sites is, of course, possible.

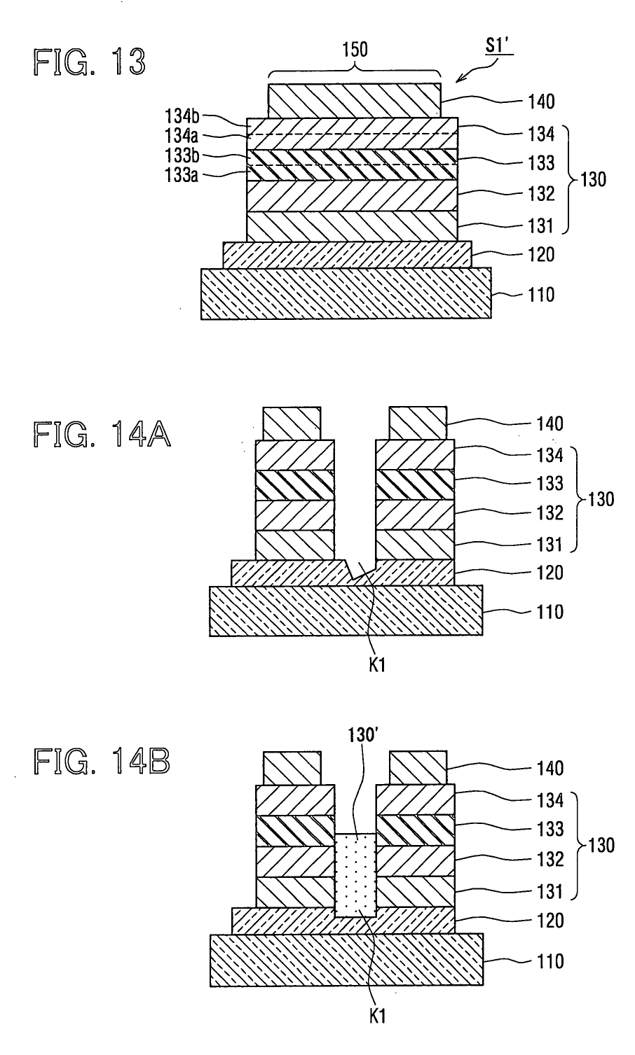

Referring now to FIG. 13, a fourth preferred embodiment will be discussed. In the fourth embodiment, the respective layers 131, 132, 133 and 134 configuring the organic layer 30 of FIG. 1 (here 130) are formed of a plurality of layers of different materials. The light-emitting layer 133 may be configured by two layers 133a and 133b, and the electron carrier layer 134 may be configured by two layers 134a and 134b, as shown by the dotted lines in FIG. 13.

(Self-Repairing Action of the Organic EL device according to the Fourth Preferred Embodiment)

In this manner, in the organic EL device S1′ where the withstand voltage of the organic layer 130 in the voltage application condition at the time of use is defined as discussed above with respect to the organic layer 30 of FIG. 1, the pixels 150 (depicted by 50 in FIG. 2) can repair themselves when a backward bias voltage equal to or less than the withstand voltage of the organic layer 130 is applied thereto.

Accordingly, the value of the backward bias voltage for self-repair can be determined to an appropriate magnitude using the withstand voltage of the organic layer 130 in the voltage application condition at the time of use as a guide. In other words, with respect to the voltage condition applied during use (see FIG. 3), the backward bias voltage applied at the time light is not to be emitted is set to a magnitude that is equal to or less than the withstand voltage of the organic layer 30, whereby setting of an excessive backward bias voltage where all of the upper electrodes 40 end up scattering can be prevented.

Additionally, self-repair can be sufficiently conducted even with a backward bias voltage of a magnitude equal to or less than the withstand voltage of the organic layer 130. This is because voltage energy and Joule heat sufficient for causing the upper electrodes 140 above defective portions can be generated even if a backward bias voltage that is lower than the withstand voltage of the organic layer 130 is applied, because the portions of the pixels 50 that are to be self-repaired are defective portions.

Also, because the withstand voltage of the organic layer 130 is used as a guide, the magnitude of the backward bias voltage is allowed as far as a magnitude that is equal to or less than the withstand voltage. Thus, a case where the backward bias voltage is too small and self-repair becomes insufficient can be prevented.

In this manner, according to the fourth embodiment, an organic EL device and an organic EL device repair method where self-repair of pixels at the time of use can be realized more reliably than has conventionally been the case can be provided.

FIGS. 14A and 14B are cross-sectional diagrams schematically showing an example of self-repair according to the fourth embodiment. FIG. 14A is an example where the upper electrode 140, the organic layer 130 and part of the lower electrode 120 have scattered at a defective portion K1 and where the space between the lower and upper electrodes 120 and 140 has become electrically open, whereby the pixel is self-repaired. FIG. 14B is an example where the lower and upper electrodes 120 and 140 have become electrically open in a state where a part 130′ of the organic layer 130 remains, whereby the pixel is self-repaired.

The self-repair shown in FIGS. 14A and 14B is conducted as follows. In a pixel 50 during use (during driving), when a minute ruptured point resulting from a short circuit arises as the defective portion K1, voltage energy and Joule heat are generated in the defective portion K1 due to the application of a self-repairable backward bias voltage.

Thus, because the upper electrode 140 flies upward and goes back outward from the end portion of the defective portion K1, the portion from which the upper electrode 140 has disappeared becomes larger than the radius of the defective portion K1. For this reason, the upper electrode 140 disappears at the end portion of the defective portion K1, the space between the lower and upper electrodes 120 and 140 becomes electrically open at this portion, and the defect does not advance any further into the surrounding area.

In other words, although a partial defect remains as the pixel 50, the withstand voltage of the pixel 50 is recovered and the pixel 50 is able to emit light, whereby self-repair is effected. Moreover, although not illustrated, the self-repair is a phenomenon in which short-circuiting with the lower electrode 120 is prevented by the remaining surface of the upper electrode 140 after scattering being oxidized and insulated is included. In this case, short-circuiting is more or less prevented even if the scattering of the upper electrode 140 is insufficient and the upper electrode 140 hangs down towards the lower electrode 120.

In the organic EL device S1 and repair method thereof in the fourth embodiment, it is preferable for the pixels 50 to be sealed with a gas including a gas that increases susceptibility to burn, such as oxygen, at 0.5% or more.

Although not specifically illustrated, this can be realized by tightly sealing the upper portion of the organic EL device S1′ with a sealing canister filled with a gas such as dry nitrogen including a gas that increases susceptibility to burn, such as oxygen, at 0.5% or more.

It is preferable to use a gas that increases susceptibility to burn, such as oxygen, in order to effectively induce self-repair. According to this, electrical opening can be more reliably conducted as a result of not only the scattering of the upper electrode 140 but also the oxidizing action (insulation) of the upper electrode 140, which is preferable.

Also, in the organic EL device S1′ and the repair method thereof in the present embodiment, it is preferable for an average surface roughness Ra to be 2 nm or less as the surface roughness of the lower electrode 120.

Specifically, in a case where the lower electrode 120 serving as the base is ITO, planarization is improved by polishing the ITO by buffing and polishing after the ITO film has been formed. More preferably, it is necessary to prevent the organic layer 130 from becoming thin at the edges of the lower electrode 120 by polishing after patterning of the ITO.

When the surface of the lower electrode 120 is too rough, the distance between the lower and upper electrodes 120 and 140 becomes too small locally. As a result, drawbacks easily arise, such as the withstand voltage of the organic layer 130 also dropping, self-repair being generated too much, and breakage of the upper electrode 140. With respect to this point, these problems can be easily avoided by setting the average surface roughness Ra of the lower electrode 120 to be 2 nm or less, which is preferable.

Next, the fourth embodiment will be more specifically described with reference to the following Specific Examples 1 to 5 serving as Examples.

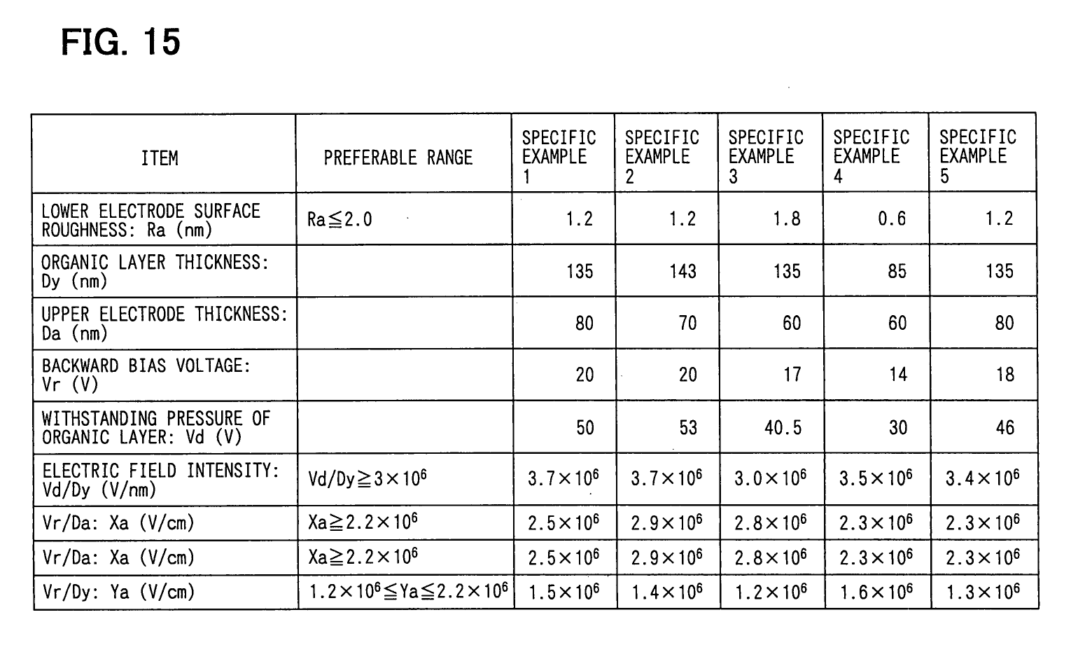

FIG. 15 is a chart showing the lower electrode surface roughness Ra (nm), the organic layer thickness Dy (nm), the upper electrode (cathode) thickness Da, the backward bias voltage Vr (V), the withstand voltage Vd (V) of the organic layer, the electric field intensity Vd/Dy (V/cm) of the withstand voltage of the organic layer, the ratio Xa and the ratio Ya of the organic EL devices S1 used in the Specific Examples 1 to 5.

In the following Specific Examples, an electric field intensity Vd/Dy′ (V/cm) per unit thickness of the organic layer when the withstand voltage Vd of the organic layer (130) was divided by an organic layer thickness Dy′ (nm) excluding the conductive organic film, and Ya′ (V/cm),which is a ratio Vr/Dy′ between the backward bias voltage Vr and the thickness Dy′ of the organic layer 130 excluding the conductive organic film, are also shown.

### SPECIFIC EXAMPLE 1

In the present example, the substrate 110 was a glass substrate and the lower electrodes (anodes) 120 were comprised of ITO films of a film thickness of about 150 nm formed by sputtering and were formed as positive-hole insertion electrodes, i.e., anodes. Also, the surfaces of the lower electrodes 120 were polished so that Ra=1.2 nm.

The organic layer 130 of the present example was formed by vacuum deposition by pretreating the ITO surface with UV ozone and then placing the ITO in a vacuum chamber. First, the positive-hole injection layer 131 was formed by forming a 15-nm film of copper phthalocyanine (CuPc). The positive-hole carrier layer 132 was formed thereon by forming a 50-nm film of alpha-naphthyl phenol benzene. The light-emitting layer 133 was formed thereon by forming a 40-nm film of quinolinol aluminum doped with 1% coumarin, and the electron carrier layer 134 was formed by forming an approximately 30-nm film of quinolinol aluminum. In this case, the color of the emitted light was green.

Moreover, the upper electrodes (cathodes) 140 were formed by laminating and vapor depositing 0.5 nm of LiF and 80 nm of Al. This panel was placed in a dry nitrogen atmosphere whose dew point was −70° C., and 1% oxygen was introduced as a gas facilitating the susceptibility to burn. Thereafter, the panel was sealed using a sealing canister.

The withstand voltage Vd of the organic layer 130 when this organic EL device S1 was driven at 120 Hz with a 1/64 duty ratio was 50 V. It should be noted that the 50-V withstand voltage of the organic layer 130 of the present example corresponded to the average withstand voltage shown in FIG. 5. The withstand voltage of the organic layer 130 was 3.7×10⁶ V/cm at the electric field intensity Vd/Dy per unit thickness of the organic layer 130.

Also, the electric field intensity Vd/Dy′ was 4.2×10⁶ V/cm when the 15-nm thickness of the copper phthalocyanine (CuPc) of the positive-hole injection layer 131 that was the conductive organic film was excluded.

Driving was conducted to become a duty ratio of 1/64, and the forward pulse (forward bias voltage) was adjusted with a constant current drive so that the initial luminance was 200 cd/m². The voltage of the forward pulse at this time was about 10 V. A 20-V backward bias pulse was applied, as the backward bias voltage Vr, at the time other than that of the forward pulse.

At this time, the ratio Xa (=Vr/Da) was 2.5×10⁶ V/cm and Ya (=Vr/Dy) was 1.48×10⁶ V/cm. Also, Ya′ (=Vr/Dy′) was 1.7×10⁶ V/cm.

When the durability of the organic EL device S1′ was evaluated, it was confirmed that no drawbacks leading to short-circuiting of the lower and upper electrodes 120 and 410 such as line defects arose, even when the organic panel S1′ was operated for 1000 hours or more at a high temperature of 80° C., and self-repair was appropriately conducted. Incidentally, as a comparative example, a backward bias voltage exceeding the 50-V withstand voltage of the organic layer 130 was applied, the panel was similarly driven and durability was evaluated, but line defects arose within 100 hours.

It should be noted that, although the concentration of oxygen in the sealing canister in Specific Example 1 was 1%, it was confirmed that there is an effect in the oxidization (insulation) of the upper electrodes 140 as long as the concentration of oxygen is 0.5% or more.

Here, modified examples of Specific Example 1 will be described. In a Modified Example 1, Xa was lower than the 2.5×10⁶ V/cm that was Xa (=Vr/Da) of Specific Example 1, and a panel S1 that was the same as the panel in Specific Example 1 was driven with a 13-V backward bias voltage (Xa=1.6×10⁶ V/cm).

As a result, line defects resulting from short-circuiting of the lower and upper electrodes 120 and 140 did not arise in high-temperature operation until 200 hours. This indicates that, although the self-repair effect was smaller than in Specific Example 1, there was a self-repair effect in comparison with the comparative example.

In a Modified Example 2, the backward bias voltage was higher in comparison to the 20-V backward bias voltage with respect to the 50-V withstand voltage of the organic layer 130 of Specific Example 1, and a panel S1 that was the same as the panel in Specific Example 1 was driven with a 30-V backward bias voltage (½ of, or less than ½ of, the withstand voltage) (Xa=3.1×10⁶ V/cm).

As a result, line defects resulting from short-circuiting of the lower and upper electrodes 120 and 140 did not arise in high-temperature operation until 700 hours. This indicates that, although the self-repair effect was smaller than in Specific Example 1, there was a self-repair effect in comparison with the comparative example.

In a Modified Example 3, Xa was lower than the 2.5×10⁶ V/cm that was Xa (=Vr/Da) of Specific Example 1, the thickness of the upper electrodes 140 was thinned to 130 nm, and a panel S1 that was the same as the panel in Specific Example 1 was driven with a 20-V backward bias voltage (Xa=1.53×10⁶ V/cm).

As a result, line defects resulting from short-circuiting of the lower and upper electrodes 120 and 140 did not arise in high-temperature operation until 600 hours. This indicates that, although the self-repair effect was smaller than in Specific Example 1, there was a self-repair effect in comparison with the comparative example.

### SPECIFIC EXAMPLE 2

In Specific Example 2, a white light-emitting element was used, the organic layer 130 was thicker and the upper electrodes (cathodes) were thinner in comparison to those in Specific Example 1 (see FIG. 15).

An ITO film of a thickness of about 320 nm was formed on the glass substrate 10 as the lower electrodes (anodes) 20. The surface of the ITO film was polished so that Ra=1.2 nm. Thereafter, the ITO surface was pretreated with UV ozone and then the ITO film was placed in a vacuum chamber.

As for the organic layer 130 of the present example, first, the positive-hole injection layer 131 was formed by forming a 15-nm film of copper phthalocyanine (CuPc), and the positive-hole carrier layer 132 was formed thereon by forming a 57-nm film of tertiary amine quadramer.

The light-emitting layer 133 had a two-layer configuration comprising a yellow light-emitting layer 133a and a blue light-emitting layer 133b successively laminated on the positive-hole carrier layer 132, so that it emitted white light as a mixed color. In the present example, the yellow light-emitting layer 133a was formed by forming a 1-nm film of tertiary amine quadramer doped with 6% rubrene. The blue light-emitting layer 133b was formed by forming a 40-nm film of an adamantane derivative doped with 5% perylene.

Next, in the present example, the electron carrier layer 134 has a two-layer configuration comprising a first electron carrier layer 134a and a second electron carrier layer 134b successively laminated on the light-emitting layer 133. The first electron carrier layer 134a was formed by forming a 20-nm film of a non-doped layer of an adamantane derivative. The second electron carrier layer 134b was formed by forming an approximately 10-nm film of quinolinol aluminum.

Moreover, the upper electrodes (cathodes) 140 were formed by laminating and vapor depositing 0.5 nm of LiF and 70 nm of Al. This panel was placed in a dry nitrogen atmosphere whose dew point was −70° C., and 1% oxygen was introduced as a gas facilitating the susceptibility to burn. Thereafter, the panel was sealed using a sealing canister.

The withstand voltage Vd of the organic layer 130 when this organic EL device S1 was driven at 120 Hz with a 1/64 duty ratio was 53 V. The withstand voltage of the organic layer 130 was 3.7×10⁶ V/cm at the electric field intensity Vd/Dy per unit thickness of the organic layer 130.

Also, the electric field intensity Vd/Dy′ was 4.1×10⁶ V/cm when the 15-nm thickness of the copper phthalocyanine (CuPc) of the positive-hole injection layer 31 that was the conductive organic film was excluded.

Driving was conducted to become a duty ratio of 1/64, and the forward pulse (forward bias voltage) was adjusted with a constant current drive so that the initial luminance was 200 cd/m². The voltage of the forward pulse at this time was about 11 V. A 20-V backward bias pulse was applied, as the backward bias voltage Vr, at the time other than that of the forward pulse.

At this time, the ratio Xa (=Vr/Da) was 2.85×10⁶ V/cm and Ya (=Vr/Dy) was 1.4×10⁶ V/cm. Also, Ya′ (=Vr/Dy′) was 1.6×10⁶ V/cm.

When the durability of the organic EL device S1′ was evaluated, it was confirmed that no drawbacks leading to short-circuiting of the lower and upper electrodes 120 and 140 such as line defects arose, even when the organic panel S1 was operated for 1500 hours or more at a high temperature operation of 80° C., and self-repair was appropriately conducted. It is thought that the self-repair function in Specific Example 2 was raised by increasing the ratio Xa.

### SPECIFIC EXAMPLE 3

In Specific Example, the surface roughness of the ITO film serving as the lower electrodes 120 was increased and the upper electrodes 140 were thinned in comparison to Specific Example 1 (see FIG. 15).

The organic EL device S1 of the present example used the panel of Specific Example 1 as a basis and the surface roughness of the ITO film was 1.8 nm.

Although it is thought that the withstand voltage of the organic layer 130 drops as a result of increasing the surface roughness of the lower electrodes 120, in actuality, the withstand voltage Vd of the organic layer 130 when this organic EL device S1 was driven at 120 Hz with a 1/64 duty ratio was 40.5 V. The withstand voltage of the organic layer 130 was 3.0×10⁶ V/cm at the electric field intensity Vd/Dy per unit thickness of the organic layer 130. Also, the electric field intensity Vd/Dy′ was 3.4×10⁶ V/cm.

Moreover, in the present example, the thickness Da of the upper electrodes (cathodes) 140 was 60 nm in order to be able to confirm that the ratio Xa (=Vr/Da) was 2.2×10⁶ V/cm or greater even when a 16.5-V backward bias voltage was applied in a case where the panel was driven at the same 120 Hz and 1/64 duty ratio as in Specific Example 1. Also, in the present example, Ya (=Vr/Dy) was 1.2×10⁶ V/cm. Ya′ (=Vr/Dy′) was 1.4×10⁶ V/cm.

When the durability of the organic EL device S1 was evaluated, it was confirmed that no drawbacks leading to short-circuiting of the lower and upper electrodes 120 and 140 such as line defects arose, even when the organic panel S1′ was operated for 1000 hours or more at a high temperature operation of 80° C., and self-repair was appropriately conducted.

### SPECIFIC EXAMPLE 4

In Specific Example 4, the surface roughness of the ITO film serving as the lower electrodes 120 was reduced and the organic layer 130 was thinned in comparison to Specific Example 1 (see FIG. 15).

The organic EL device S1′ of the present example used the panel of Specific Example 1 as a basis. The surface roughness Ra of the ITO film was reduced to 0.6 nm, the thickness of the positive-hole insertion layer 131 was kept at 15 nm, the thickness of the positive-hole carrier layer 132 was reduced to 30 nm, the thickness of the light-emitting layer 133 was reduced to 30 nm, and the thickness of the electron carrier layer 134 was reduced to 10 nm.

The withstand voltage Vd of the organic layer 130 when this organic EL device S1 was driven at 120 Hz with a 1/64 duty ratio was 30 V. The withstand voltage of the organic layer 130 was 3.5×10⁶ V/cm at the electric field intensity Vd/Dy per unit thickness of the organic layer 130. Also, the electric field intensity Vd/Dy′ was 4.3×10⁶ V/cm.

Moreover, in the present example, the thickness Da of the upper electrodes (cathodes) 140 was 60 nm in order to be able to confirm that the ratio Xa (=Vr/Da) was 2.2×10⁶ V/cm or greater even when a 14-V backward bias voltage was applied in a case where the panel was driven at the same 120 Hz and 1/64 duty ratio as in Specific Example 1. Also, in the present example, Ya (=Vr/Dy) was 1.6×10⁶ V/cm. Ya′ (=Vr/Dy′) was 2.0×10⁶ V/cm.

When the durability of the organic EL device S1′ was evaluated, it was confirmed that no drawbacks leading to short-circuiting of the lower and upper electrodes 120 and 140 such as line defects arose, even when the organic panel S1′ was operated for 1000 hours or more at a high temperature operation of 80° C., and self-repair was appropriately conducted.

### SPECIFIC EXAMPLE 5

In Specific Example 5, the duty ratio was changed in the drive application voltage and the withstand voltage 130 was changed in comparison to Specific Example 1 (see FIG. 15).

Using the same organic EL device S1′ as in Specific Example 1, the withstand voltage Vd of the organic layer 130 when this organic EL device S1 was driven at 120 Hz with a 1/32 duty ratio was 46 V, which was smaller than in Specific Example 1. The withstand voltage of the organic layer 130 was 3.4×10⁶ V/cm at the electric field intensity Vd/Dy per unit thickness of the organic layer 130. Also, the electric field intensity Vd/Dy′ was 3.8×10⁶ V/cm.

Driving was conducted to become a duty ratio of 1/32, and the forward pulse (forward bias voltage) was adjusted with a constant current drive so that the initial luminance was 200 cd/m². The voltage of the forward pulse at this time was about 8 V. An 18-V backward bias pulse was applied, as the backward bias voltage Vr, at the time other than that of the forward pulse.

At this time, the ratio Xa (=Vr/Da) was 2.3×10⁶ V/cm and Ya (=Vr/Dy) was 1.33×10⁶ V/cm. Also, Ya′ (=Vr/Dy′) was 1.5×10⁶ V/cm.

When the durability of the organic EL device S1′ was evaluated, it was confirmed that no drawbacks leading to short-circuiting of the lower and upper electrodes 120 and 140 such as line defects arose, even when the organic panel S1′ was operated for 1000 hours or more at a high temperature operation of 80° C., and self-repair was appropriately conducted.

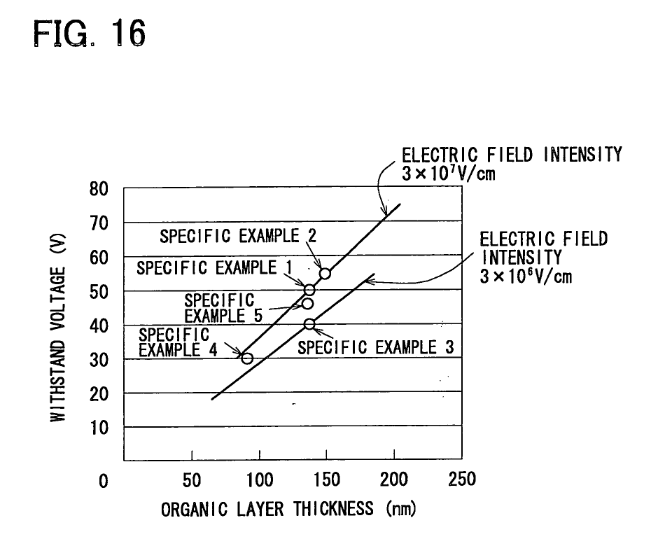

In all of the preceding Specific Examples 1 to 5, the electric field intensity per unit thickness of the organic layer 130 was 3×10⁶ V/cm or greater as the withstand voltage of the organic layer 30. FIG. 16 is a graph showing the relation between the relation between the thickness (nm) of the organic layers 130 and the average withstand voltage (V) of the organic layers 130 that the present inventors investigated. The electric field intensities of Specific Examples 1 to 5 are also plotted.

As shown in FIG. 16, according to the investigations of the present inventors, it was understood that the withstand voltage of the organic layer 130 in the organic EL device can be defined by the total thickness thereof regardless of the type of organic material. Additionally, the self-repair effect was sufficiently exhibited in Specific Examples 1 to 5 where the electric field intensity was 3×10⁶ V/cm or greater.

It should be noted that, other than a panel including plural pixels such as a dot matrix type, the organic EL device may also be configured by a single pixel. In this case, the withstand voltage of the organic layer may be determined as the average withstand voltage using plural panels of the same configuration.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. An organic EL panel comprised of a plurality of pixels, each of the plurality of pixels comprising an organic layer disposed between a lower electrode and an upper electrode,
wherein the plurality of pixels repair themselves when a backward bias voltage equal to or less than a withstand voltage of the organic layer in a voltage application condition at a time of use is applied thereto.

2. The organic EL panel of claim 1, wherein the organic layer includes a light-emitting layer disposed between the lower electrode and the upper electrode.

3. The organic EL panel of claim 1, further comprising a resin protective film comprising a resin disposed on the upper electrode to cover the plurality of pixels, the resin protective film including oxygen as a constituent element,
whereby the resin protective film decomposes and releases a low molecular weight substance including oxygen when the lower and upper electrode short-circuit and when the backward bias voltage equal to or less than the withstand voltage of the organic layer in the voltage application condition at the time of use is applied.

4. The organic EL panel of claim 3, wherein the upper electrode and the organic layer are successively laminated on the lower electrode.

5. The organic EL display device of claim 3, wherein the resin protective film comprises a silicon resin.

6. The organic EL display device of claim 3, wherein the resin protective film comprises a fluororesin.

7. The organic EL display device of claim 3, further comprising an inorganic protective film comprised of inorganic matter, wherein the inorganic protective film is intervened between the resin protective film and the upper electrode, is formed by atomic layer epitaxy and the film thickness thereof is 200 nm or less.

8. The organic EL display device of claim 3, further comprising a gas-trapping getter inserted between the upper electrode and the resin protective film.

9. The organic EL display device of claim 3, further comprising a laminate film comprising metal foil or a laminate sheet formed by adhering together a metal film and resin films disposed on the resin protective film, wherein the laminate film is for shielding the plurality of pixels and the resin protective film from outside air.

10. The organic EL display device of claim 3, wherein the resin protective film comprises a desiccant mixed therein.

11. The organic EL panel of claim 1, wherein the withstand voltage of the organic layer is determined when the organic EL panel is driven for 1 minute or less in the voltage application condition at the time of use.

12. The organic EL panel of claim 1, wherein the backward bias voltage is ½ of, or less than ½ of, the withstand voltage of the organic layer.

13. The organic EL panel of claim 1, wherein an electric field intensity of the organic layer is 3×10⁶ V/cm or greater when the withstand voltage of the organic layer is expressed as an electric field intensity per unit thickness of the organic layer.

14. The organic EL panel of claim 1, wherein an electric field intensity of the organic layer is 3.4×10⁶ V/cm or greater excluding a conductive organic film from the organic layer when the withstand voltage of the organic layer is expressed as an electric field intensity per unit thickness of the organic layer.

15. The organic EL panel of claim 1, wherein when the backward bias voltage is represented as Vr, the thickness of the upper electrodes is represented as Da, and the ratio Vr/Da between Vr and Da is represented as Xa, Xa is 2.2×10⁶ V/cm or greater.

16. The organic EL panel of claim 15, wherein Xa is 2.2×10⁶ V/cm or greater as a result of the thickness Da of the upper electrodes being thinned to 100 nm or less.

17. The organic EL display device of claim 15, wherein the thickness Da of the upper electrodes is thinned to 100 nm or less, whereby Xa is 2.2×10⁶ V/cm or greater.

18. The organic EL panel of claim 1, wherein when the backward bias voltage is represented as Vr, the thickness of the organic layer is represented as Dy, and the ratio Vr/Dy between Vr and Dy is represented as Ya, Ya is 1.2×10⁶ V/cm or greater and 2.2×10⁶ V/cm or less.

19. The organic EL panel of claim 1, wherein when the backward bias voltage is represented as Vr, the thickness of the organic layer excluding a conductive organic film is represented as Dy′, and the ratio Vr/Dy′ between Vr and Dy′ is represented as Ya′, Ya′ is 1.4×10⁶ V/cm or greater and 2.4×10⁶ V/cm or less.

20. The organic EL panel of claim 1, wherein the plurality of pixels are sealed with a gas including a gas that increases susceptibility to burn at 0.5% or more.

21. The organic EL panel of claim 1, wherein an average surface roughness Ra is 2 nm or less as the surface roughness of the lower electrode.

22. A method for repairing an organic EL panel comprised of a plurality of pixels, each of the plurality of pixels comprises an organic layer, a lower electrode and an upper electrode, wherein the organic layer includes a light-emitting layer disposed between the lower electrode and the upper electrode, the method comprising:
applying a backward bias voltage equal to or less than the withstand voltage of the organic layer in a voltage application condition at a time of use so that the pixels repair themselves.

23. The method of claim 22, wherein the withstand voltage when the organic EL panel is driven for 1 minute or less in the voltage application condition at the time of use is used as the withstand voltage of the organic layer.

24. The method of claim 22, wherein a voltage that is ½ of, or less than ½ of, the withstand voltage of the organic layer is used as the backward bias voltage.

25. The method of claim 22, an electric field intensity of the organic EL panel is 3×10⁶ V/cm or greater when the withstand voltage of the organic layer is expressed as an electric field intensity per unit thickness of the organic layer.

26. The method of claims 22, wherein an electric field intensity of the organic EL panel is 3.4×10⁶ V/cm or greater excluding a conductive organic film from the organic layer in a case when the withstand voltage of the organic layer is expressed as an electric field intensity per unit thickness of the organic layer.

27. The method of claim 22, wherein when the backward bias voltage is represented as Vr, the thickness of the upper electrodes is represented as Da, and the ratio Vr/Da between Vr and Da is represented as Xa, Xa is 2.2×10⁶ V/cm or greater.

28. The method of claim 27, wherein Xa is 2.2×10⁶ V/cm or greater as a result of thinning the thickness Da of the upper electrodes to 100 nm or less.

29. The method of claim 22, wherein when the backward bias voltage is represented as Vr, the thickness of the organic layer is represented as Dy, and the ratio Vr/Dy between Vr and Dy is represented as Ya, Ya is 1.2×10⁶ V/cm or greater and 2.2×10⁶ V/cm or less.

30. The method of claim 22, wherein when the backward bias voltage is represented as Vr, the thickness of the organic layer excluding a conductive organic film is represented as Dy′, and the ratio Vr/Dy′ between Vr and Dy′ is represented as Ya′, Ya′ is 1.4×10⁶ V/cm or greater and 2.4×10⁶ V/cm or less.

31. The method of claim 22, wherein the applying of the backward bias voltage is conducted in a state where the pixels are sealed with a gas including a gas that increases susceptibility to burn at 0.5% or more.

32. The method of claim 31, wherein a panel is used where an average surface roughness Ra is 2 nm or less as the surface roughness of the lower electrodes.

33. The method of claim 22, wherein a panel is used where an average surface roughness Ra is 2 nm or less as the surface roughness of the lower electrodes.

34. An organic EL display device comprising:
a pixel that comprises a lower electrode, an organic layer including a light-emitting layer and an upper electrode successively laminated; and
a resin protective film comprising a resin disposed on the upper electrodes so as to cover the pixel, the resin protective film including oxygen as a constituent element, whereby the resin protective film decomposes and releases a low molecular weight substance including oxygen when the lower and upper electrodes short-circuit and when a backward bias voltage equal to or less than a withstand voltage of the organic layer in a voltage application condition at the time of use is applied.

35. The organic EL display device of claim 34, wherein when the backward bias voltage is represented as Vr, the thickness of the organic layer is represented as Dy, and the ratio Vr/Dy between Vr and Dy is represented as Ya, Ya is 1.2×10⁶ V/cm or greater and 2.2×10⁶ V/cm or less.

36. The organic EL display device of claim 34, wherein when the backward bias voltage is represented as Vr, the thickness of the organic layer excluding a conductive organic film is represented as Dy′, and the ratio Vr/Dy′ between Vr and Dy′ is represented as Ya′, Ya′ is 1.4×10⁶ V/cm or greater and 2.4×10⁶ V/cm or less.
